(19) United States
(12) Patent Application Publication
(10) Pub. No.: US 2010/0213945 A1
(43) Pub. Date: Aug. 26, 2010

(54) System and Method of Monitoring an Electronic Discharge Device in an Air Purification System

(75) Inventors: Kenneth E. GILLELAND, Long Beach, CA (US); Robert M. CULBERT, Manhattan Beach, CA (US); Robert SCHEIR, Sherman Oaks, CA (US); Richard MUELLER, Burbank, CA (US)

Correspondence Address: ROTHWELL, FIGG, ERNST & MANBECK, P.C., 1425 K STREET, N.W., SUITE 800, WASHINGTON, DC, 20005, US

(73) Assignee: STERIL-AIRE, INC., Burbank, CA (US)

(21) Appl. No.: 12/580,581

(22) Filed: Oct. 16, 2009

Related U.S. Application Data
(60) Provisional application No. 61/106,366, filed on Oct. 17, 2008.

(51) Int. Cl. G01R 31/24

(52) U.S. Cl. 324/414; 324/403

(57) ABSTRACT

A method and system of remotely monitoring an operational status of electronic discharge devices in an air purification system senses emitted radiation at a location proximate the air purification system, alone or in combination with a determination of an amount of time remaining in an operational lifetime of the electronic discharge device, or an amount of power delivered to at least one of the electronic discharge devices. A determination of the operational status of at least one of the electronic discharge devices is made based on at least emitted radiation, and the status information is transmitted to a remote monitoring unit that receives the status information and displays an indicator of operational status. In one embodiment, the operational status of a UV-C germicidal lamp may be monitored using optically sensitive devices located within a purification system.

### CROSS REFERENCE TO RELATED APPLICATION

This application claims priority to U.S. Provisional Application Ser. No. 61/106,366, filed Oct. 17, 2008, the entire contents of which are incorporated herein by reference.

### BACKGROUND OF THE INVENTION

I. Field of the Invention

The present invention relates generally to air purification systems. More particularly, the present invention relates to a system and method of monitoring air purification systems that utilize one or more electronic discharge devices.

II. Discussion of the Related Art

Air purification systems may be used to address growing concerns over pollution, air-born biological materials, allergens, and the need to provide a clean environment for the production of advanced electronic materials. Such air purification systems sometimes use an electronic discharge device (EDD) installed in heating, ventilation, and air conditioning (HVAC) systems. The electronic discharge device provides germicidal treatment using ultra-violet (UV) radiation to eradicate harmful microorganisms in the air and on surfaces of an air handling unit of the air purification system. Optimum performance of an air purification system depends on the electronic discharge devices operating at peak efficiency.

Electronic discharge devices commonly used in air purification systems have a finite lifetime and must be replaced periodically. In current systems, a device may malfunction, unknown to a maintenance provider, resulting in a significant delay in replacing the device. Degradation in performance due to the device malfunctioning may substantially reduce purification capabilities of the system.

Some air purification systems are provided with status indicators, for example, a status indicator window or a light-emitting diode (LED). Some air purification systems are mounted on air handling units with limited physical access making it difficult to view the status indicator window or LED. It may also be difficult to monitor an operational status of a particular electronic discharge device when the status indicator is provided at a location proximate the purification system.

Additionally, typical electronic discharge device status indicators use electrical properties such as voltage, current, and resistance sensed at various locations within the device to determine an operational status of an electronic discharge device. Such configurations are ill-suited for retro-fitting and may not be able to provide a comprehensive description of a status of an electronic discharge device.

### SUMMARY OF THE INVENTION

It is therefore a primary object of the present invention to overcome disadvantages of the prior art by providing an improved system and method of monitoring an operational status of an electronic discharge device in an air purification system. The system and method may be provided by an original equipment manufacturer (OEM) or as a retrofit to an existing air purification system.

The present invention achieves this object by providing a system of monitoring an operational status of an electronic discharge device in an air purification system that includes a sensor located proximate an air purifying system and configured to detect an operational characteristic of an electronic discharge device in an purification system and a sensing circuit located proximate the air purification system and configured to receive input signals from the sensor, determine an operational status of the electronic discharge device in response to the operational characteristic detected, and transmit a signal indicating the operational status of the electronic discharge device to a remote location. In an embodiment, the sensor includes a photodiode that is sensitive to ultra-violet radiation.

In an embodiment, the sensor includes a mounting device configured to mount the sensor to an electronic discharge device. In another embodiment, the sensor includes a masking element formed of opaque material configured to prevent cross-illumination from any adjacent electronic discharge devices. In an embodiment, the system may include a monitoring unit configured to receive the signal from the sensing circuit and display an indicator of the operational status of the electronic discharge device.

In another embodiment, a system of monitoring an operational status of an electronic discharge device in an air purification system includes an optically sensitive detector configured to detect radiation emitted from an electronic discharge device and located within an purification system and in an optical path of radiation emitted from the electronic discharge device, wherein the detector is configured to generate a signal in response to a level of radiation detected and a sensing circuit configured to receive input signals from the optically sensitive detector and determine an operational status of the electronic discharge device in response to the optical radiation detected. In an embodiment, the system may include a monitoring unit configured to receive a signal from the sensing circuit and display an indication of the operational status of the electronic discharge device.

The present invention also relates to a method of remotely monitoring an operational status of an electronic discharge device in an air purification system comprises sensing an operational characteristic of an electronic discharge device of an air purification system, determining an operational status of the electronic discharge device in response to the operational characteristic sensed, and transmitting a signal indicating the operational status of the electronic discharge device to a remote location.

In an embodiment, the electronic discharge device includes an ultra-violet (UV) lamp configured to emit germicidal UV-C radiation. In another embodiment, the operational characteristic sensed includes emitted radiation, alone or in combination with an amount of operational lifetime remaining for the electronic discharge device, and/or an amount of power delivered to the electronic discharge device. In an embodiment, light-emitting diodes (LED) display any one of sensor information, operational lifetime information, and electronic discharge device power information.

In an embodiment, a method of remotely monitoring an operational status of an electronic discharge device in an air purification system includes sensing optical radiation emitted from an electronic discharge device using an optically sensitive detector located within an purification system and in an optical path of the radiation emitted from the electronic discharge device, generating a signal in response to the optical radiation sensed, determining an operational status of the electronic discharge device using the signal generated by the optically sensitive detector, and transmitting a signal indicating the operational status of the electronic discharge device to a remote location. In an embodiment, the method may also include receiving the signal at the remote location and displaying an indication of the operational status of the electronic discharge device at the remote location.

In yet another embodiment, a method of retrofitting an existing air purification system for monitoring an operational status of an electronic discharge device in an air purification system including accessing an existing air purification system comprising an electronic discharge device located within an air handling unit wherein the electronic discharge device is configured to expose air moving through the unit to radiation and installing within the purification system and in an optical path of the radiation emitted from the electronic discharge device an optically sensitive device to detect radiation emitted from the electronic discharge device.

Some of the advantages of the present invention are that a facilities manager or other individual may monitor an operational status of an air purification system from a location that is physically remote from the air purification system, such as from an office or central panel, reducing a delay in replacing or servicing malfunctioning electronic discharge devices, reducing an amount of time an air purification system operates at a reduced level of efficiency, and existing air purification systems may be retrofitted with remote monitoring to provide for these advantages.

Other objects and advantages of the present invention will become apparent to those of skill in the art upon reviewing the detailed description of the preferred embodiments and accompanying drawings.

### BRIEF DESCRIPTION OF THE DRAWINGS

The accompanying drawings, which are incorporated herein and form part of the specification, illustrate various embodiments of the present invention and, together with the description, further serve to explain the principles of the invention and to enable a person skilled in the pertinent art to make and use the invention. In the drawings, like reference numbers indicate identical or functionally similar elements.

FIG. 1 is a diagram showing part of an electronic discharge device monitoring system for use with an air purification system according to an embodiment of the present invention.

FIG. 2A is a diagram showing an embodiment of the monitoring system in conjunction with an air purification system utilizing a plurality of electronic discharge devices disposed within an air handling unit.

FIG. 2B is an enlarged view of a monitoring system sensor mounted on an electronic discharge device with a shield according to an embodiment of the present invention.

FIG. 3 is a diagram showing a remote monitoring system for an air purification system in an air handling unit according to an embodiment of the present invention.

FIG. 4 is a sensing circuit for an electronic discharge device monitoring system according to an embodiment of the present invention.

FIG. 5 is a flowchart of a method of monitoring an electronic discharge device in an air purification system according to an embodiment of the present invention.

### DESCRIPTION OF THE PREFERRED EMBODIMENTS

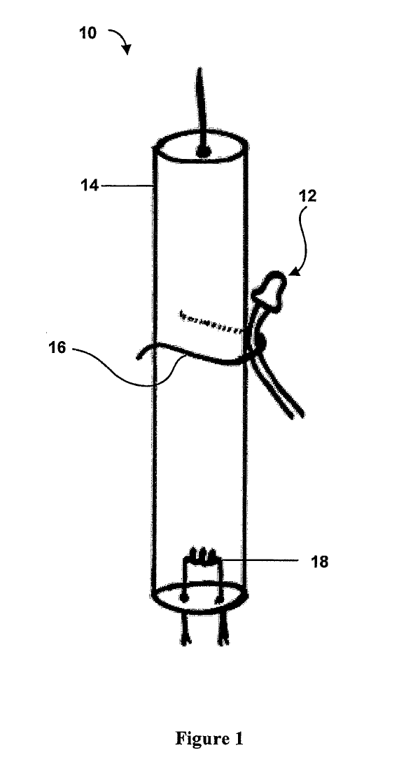

FIG. 1 shows an embodiment of an electronic discharge device (EDD) monitoring system 10 for an air purification system according to the present invention. The system 10 includes a sensor 12 mounted in relation to an EDD 14 of an air purification system to monitor an operational characteristic of the EDD. The term “operational characteristic,” as used herein, refers to a physical property of the EDD that relates to operational status or performance such as, for example, an amount of radiation emitted by the EDD. In accordance with the present invention, the sensor 12 detects an operational characteristic of the EDD and generates a signal indicative of the operational status of the EDD.

In a preferred embodiment, the sensor 12 is an optical detector, such as a photodiode or a photoresistor, operable to detect the amount of germicidal radiation emitted from the EDD 14. The electronic discharge device 14 may be a fluorescent, mercury vapor, ultra-violet (UV), low pressure sodium, high pressure or other lamp made of glass, metal, plastic or other material to provide radiation to eradicate harmful microorganisms in the air and on surfaces of an air handling unit. In a preferred embodiment, the sensor 12 is mounted in relation to an EDD 14 in the form of an ultra-violet (UV) lamp configured to emit germicidal UV-C radiation with a wavelength of approximately 250-260 nm. The UV lamps 14 may be, for example, of the single or double ended variety and have a straight, J-shaped, or U-shaped tube.

The sensor 12 is preferably attached directly to the EDD 14, in the path of emitted radiation, using a mounting mechanism 16. According to an embodiment, the mounting mechanism 16 is a resilient clip that detachably mounts the sensor 12 to an external surface of the EDD 14. In the embodiment shown, the mounting mechanism 16 is a semicircular clip with out-turned ends. The clip 16 is preferably formed of a heat resistant, elastic material, such as stainless steel, and has a radius of curvature slightly smaller than a radius of curvature of the lamp 14 so that, when installed around the lamp as shown, the clip is elastically deformed outward and caused to exert an inwardly directed mounting pressure against the lamp. The out-turned ends of the clip 16 facilitate installation and removal of the clip without the need of tools.

According to an embodiment, the sensor 12 is mounted at a central location along a longitudinal axis of the EDD 14, preferably at least several inches from the filament 18. This location maximizes exposure to emitted radiation while reducing heating of the sensor 12 by the filament 18 that can potentially interfere with performance and reliability of the system. It is to be understood that the sensor 12 may be used either alone or in combination with other sensors to monitor operational status of the air purification system. For example, the sensor 12 may be used with other status indicators such as, for example, operational life and purification system power indicators.

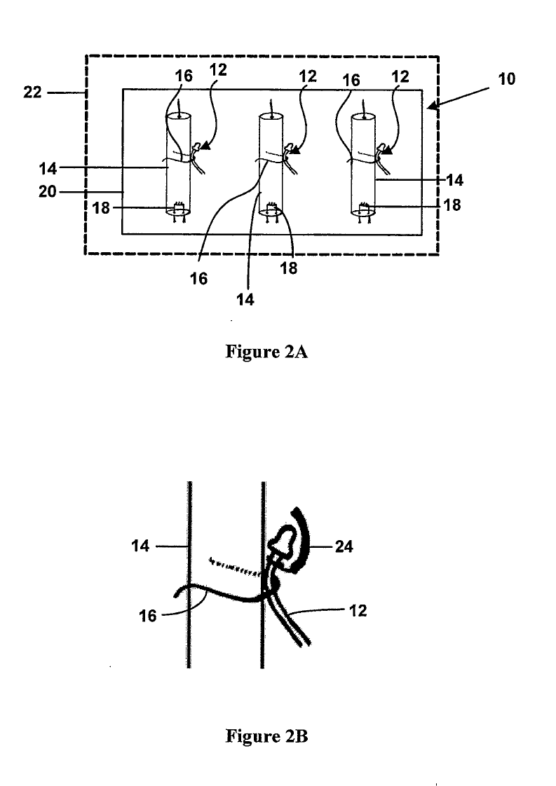

FIG. 2A shows an embodiment of the monitoring system 10 configured for use with an air purification system 20 that includes a plurality of electronic discharge devices 14 located within an air handling unit 22, such as an HVAC system (e.g., like the air purification systems shown and described in U.S. Pat. Nos. 5,334,347 and 5,817,276, the disclosures of which are incorporated herein by reference). The monitoring system 10 includes a plurality of sensors 12 mounted on a plurality of EDDs 14 using a plurality of mounting mechanisms 16 to monitor an operational characteristic of each EDD.

The plurality of optically sensitive sensors 12 may be installed within the air purification system 20 to monitor an amount of radiation emitted by the electronic discharge devices 14. The sensors 12 are preferably located near the electronic discharge device 14 and in an optical path of emitted radiation such that the sensor 12 may detect radiation emitted under normal operating conditions. Preferably, the sensors 12 are mounted at a central location along a longitudinal axis of the EDD and are of a size that does not interfere with the germicidal treatment process by blocking radiation.

According to an embodiment, shown in FIG. 2B, a shield 24 may be provided on each sensor 12 to reduce cross-illumination from adjacent electronic discharge devices 14. The shield 24 enables the sensors 12 to detect a more accurate amount of radiation being emitted from the electronic discharge device 14 to which the sensor 12 is mounted. According to an embodiment, the shield 24 may be, for example, a masking element disposed between the sensor 12 and an adjacent electronic discharge device 14 and formed of material opaque to ultra-violet C (UVC) radiation. The shield 24 is shown as a curved element that extends around a side of the sensor 12 opposite the EDD 14, although other shield configurations may be used. The shield 24 may also be configured to be manually detachable from the sensor 12 such that the shield may be reattached or attached to a replacement sensor 12, if desired.

It will be appreciated that the sensors 12 provide a reliable measure of actual performance of an electronic discharge device 14 by detecting the presence of germicidal radiation in the air purification system 20. The sensors 12 are configured to generate a signal, such as a voltage or current signal, in response to a level of radiation detected, thereby giving an indication of the performance of the electronic discharge device 14.

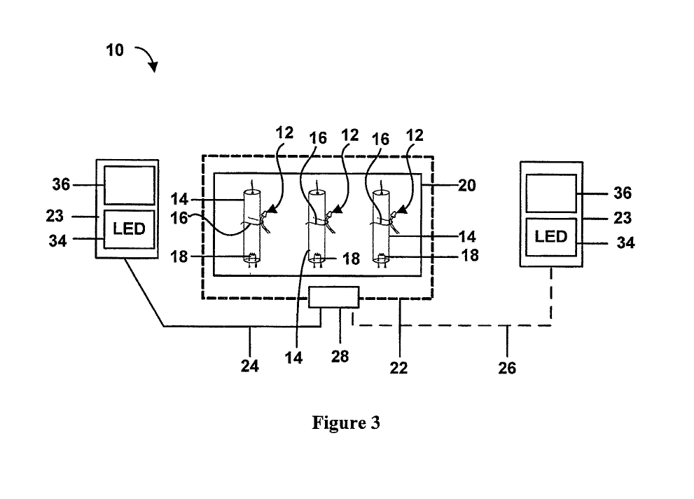

Referring to FIG. 3, it can be seen that the signals generated by the sensors 12 may be received by a sensing circuit 28 that transmits a status signal to a remote monitoring unit 23. The remote monitoring unit 23 may be positioned at a location that is not proximate the air handling unit 22, thereby allowing an individual such as a facilities engineer or other individual to monitor the status of one or more electronic discharge devices 14 within an air purification system 20 without needing to be in visual range of the system. In accordance with an embodiment of the present invention, the remote monitoring unit 23 may be configured with a passive reception device 36 that receives a status signal from the sensing circuit 28. Use of passive electronics at the back end reduces cost, thus providing a cost effective and easily implemented method of monitoring the status of electronic discharge devices within an air purification system from multiple locations. Additionally, the use of passive devices reduces a likelihood of interference among devices when multiple monitoring systems 10 are being used. It will be appreciated that the sensor circuit 28 may send a status signal to the remote monitoring unit 23 over a wired connection 24 or a wireless connection 26.

The remote monitoring unit 28 is configured to provide a sensible indication of the operational status of the electronic discharge devices 14. In a preferred embodiment, the indicator may be a visible indicator such as a light emitting diode (LED) 34 that shows a predetermined color corresponding to a detected operational status of the EDDs. If desired, a plurality of indicators corresponding to the number of EDDs may be used so that a user may determine which of the EDDs is malfunctioning and in need of replacement. The indicator 34 on the remote monitoring unit 23 may also display, or be combined with other indicators that display, other operational characteristics such as operational lifetime information, and electronic discharge device power information.

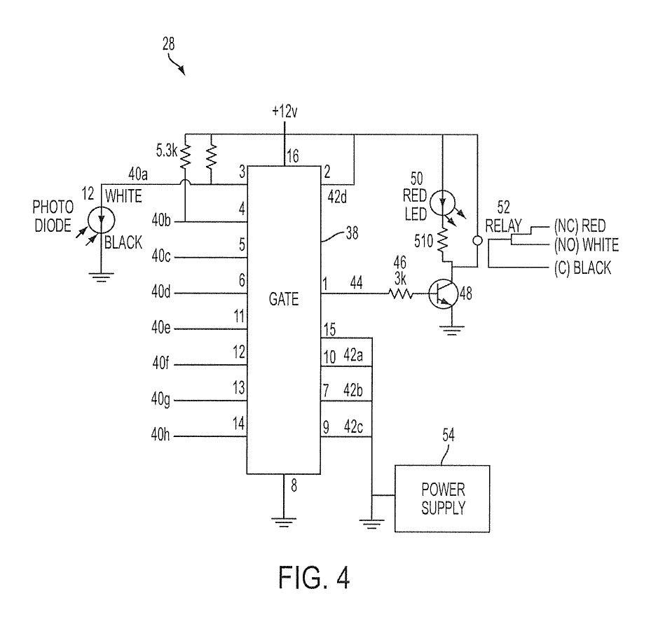

FIG. 4 shows an embodiment of a sensing circuit 28 according to the present invention. The sensing circuit 28 may include a multifunction gate 38 having inputs 40a-40h. The sensing circuit 28 is configured to receive input signals from the sensors 12 using one or more of the inputs 40a-40h. If there are fewer than eight (8) inputs, a dual in-line package (DIP) switch may be used to configure the multifunction gate 38. The multifunction gate 38 may include one or more binary control inputs 42a-42c to control the implementation of different logic functions. In an embodiment, binary control input 42d may be used to control whether output 44 is set as a logic “1” or a logic “0” in response to inputs 40a-40h and the inner states of the multifunction gate 38.

The sensing circuit 28 is configured to determine an operational status of the electronic discharge devices 14 in response to the signal received from sensors 12 using inputs 40a-40h. An output signal that indicates the state of the multifunction gate 38 is communicated using the output 44. In an embodiment, the multifunction gate 38 may be configured as an AND gate. In this configuration, the multifunction gate 38 sets output 44 as logic “1” if all inputs 40a-40h receive a signal from sensors 12 above a given threshold. The level of the signal delivered from sensors 12 is dependent on the sensed intensity of radiation from the electronic discharge devices 14. If not all sensors 12 receive a signal above the given threshold, the output 44 will be a logic “0”. Thus, a determination of operational status may be made on the basis of output 44. The operational status may refer to how well the electronic discharge device 14 is performing. For example, an operational status may be “fully operational”, “reduced capacity”, “malfunction” or other status.

The output 44 is connected to a sensing resistor 46 and a switch 48. The switch 48 is controlled by the output 44, and may be in the “ON” or “OFF” position depending on whether output 44 is a logic “1” or logic “0”. The switch 48 may be connected to a light-emitting diode (LED) 50 such that the LED 50 may be used to provide a visual indication regarding the operational status of the electronic discharge device 14. For example, a red LED 50 may be used to indicate a malfunction status of the electronic discharge device 14 depending upon the state of output 44. The sensing circuit 52 may also include a relay 52 that may be connected to one or more LEDs 50 to provide additional operational status indications to a remote monitoring unit at a remote location.

The sensing circuit 28 may also include a commercially available power supply 54 and a timer that indicates an operational lifetime remaining for the electronic discharge device 14. The timer may be used in conjunction with the LED 50 to indicate the operational lifetime remaining.

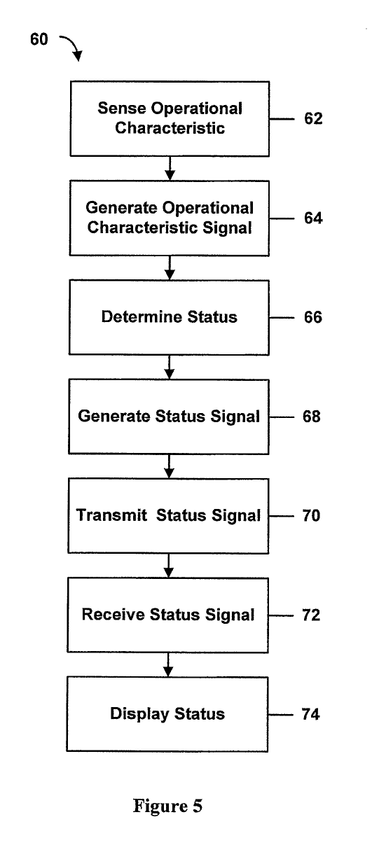

FIG. 5 shows a method 60 of remotely monitoring an electronic discharge device in an air purification system according to an embodiment of the invention. The method 60 may begin at step 62 where a sensor senses an operational characteristic of the electronic discharge device. As discussed above, the sensor may be, for example, an optically sensitive detector and the optical characteristic may be, for example, an amount of radiation emitted from an electronic discharge device, an amount of operational lifetime remaining for an electronic discharge device, whether the electronic discharge device is receiving power or other characteristic.

An operational characteristic signal may be generated in step 64 that is indicative of the operational characteristic sensed in step 62. Using the operational characteristic signal, a status of the electronic discharge device may be determined in step 66. The status may be, for example, “fully operational”, “reduced capacity”, “malfunction” or other status.

A status signal indicating the status of the electronic discharge device may be generated in step 68. The status signal may be transmitted, in step 70, to a monitoring unit such as, for example, a control panel. According to an embodiment, the monitoring unit may be in a remote location. The status signal may be received by the monitoring unit in step 72. A status of the electronic discharge device, based on the status signal received, may be displayed in step 74 using any display device.

Regarding another aspect of the present invention, the above referenced components, systems, and methods may be implemented in a pre-existing air purification system containing an electronic discharge device used to expose air moving through the unit to radiation specifically targeted to improve air quality. By accessing an existing the air purification system and installing an optically sensitive device sufficiently near the electronic discharge device to detect radiation emitted, for example, under normal operating conditions, the pre-existing air purification system may be configured for remote monitoring using the method described above.

While the invention has been particularly taught and described with reference to certain preferred embodiments, those versed in the art will appreciate that minor modifications in form and detail may be made without departing from the spirit and scope of the invention. For example, the sensing circuit may include a gate device with fewer or more inputs, multiple gate devices, or a DIP switch to tailor the number of sensor inputs. In an alternate embodiment, the sensing circuit may be configured to identify a specific lamp that is malfunctioning. Furthermore, while the mounting mechanism is shown as a resilient, semicircular clip, it will be appreciated that various other mounting mechanisms can be used, including but not limited to U-shaped or C-shaped clips, clamps that extend partially or completely around the lamp, cable ties, bands that wrap around the lamp, or adhesives.

All of the foregoing changes, modifications and alterations should be considered within the scope of the present invention as set forth in the appended claims.

What is claimed is:

1. A method of remotely monitoring an operational status of an electronic discharge device in an air purification system comprising:
sensing a first operational characteristic of an electronic discharge device of an air purification system;
determining an operational status of the electronic discharge device in response to the operational characteristic sensed; and
transmitting a status signal indicating the operational status of the electronic discharge device to a location remote from the electronic discharge device.

2. The method of claim 1, wherein the electronic discharge device includes an ultra-violet (UV) lamp configured to emit germicidal radiation and the first operational characteristic sensed includes radiation emitted from the lamp.

3. The method of claim 2, further comprising sensing a second operating characteristic of the electronic discharge device.

4. The method of claim 3, wherein the second operating characteristic includes at least one of an amount of operational lifetime remaining for the electronic discharge device, and an amount of power delivered to the electronic discharge device.

5. The method of claim 1, wherein the transmitting step comprises using one of a wired connection and a wireless connection.

6. The method of claim 1, further comprising receiving the status signal at the remote location.

7. The method of claim 5, wherein the receiving step uses a passive reception device.

8. The method of claim 1, further comprising displaying, at the remote location, a visual indicator of the operational status of the electronic discharge device.

9. The method of claim 7, wherein the displaying step includes using a light-emitting diode (LED).

10. The method of claim 8, wherein the light-emitting diode (LED) displays a plurality of colors corresponding to an operational characteristic of the electronic discharge device.

11. The method of claim 1, further comprising mounting a light sensor adjacent the electronic discharge device.

12. The method of claim 10, wherein said mounting step includes attaching the light sensor to the electronic discharge device.

13. The method of claim 11, further comprising mounting a shield between the light sensor and an adjacent electronic discharge device.

14. The method of claim 11, wherein the air purification system includes a plurality of electronic discharge devices, and further comprising mounting a plurality of light sensors adjacent the plurality of electronic discharge devices.

15. The method of claim 14, wherein at least some of the sensors are disposed between pairs of electronic discharge devices, and further comprising installing a shield between a sensor and one of the pair of electronic discharge devices.

16. The method of claim 14, further comprising indicating a failure if one or more of the electronic discharge devices is determined to be inoperable.

17. The method of claim 16, wherein said indicating step includes displaying a visual indicator adjacent the air purification system.

18. The method of claim 16, wherein said indicating step includes displaying a visual indicator at a remote location that is not visible from the air purification system.

19. A system of remotely monitoring an operational status of an electronic discharge device in an air purification system comprising:
a sensor located proximate an air purification system and configured to detect a level of radiation emitted from an electronic discharge device in the purification system; and
a sensing circuit configured to receive input signals from the sensor and determine an operational status of the electronic discharge device in response to the level of radiation detected.

20. The system of claim 19, wherein the sensor is configured to generate an operational characteristic signal in response to the level of radiation detected.

21. The system of claim 19, wherein the sensing circuit is configured to generate a status signal indicating a status of the electronic discharge device in response to the operational characteristic signal.

22. The system of claim 21, wherein the sensing circuit is configured to transmit the status signal indicating the operational status of the electronic discharge device.

23. The system of claim 22, further comprising a monitoring unit configured to receive the status signal from the sensing circuit and display an indication of the operational status of the electronic discharge device.

24. The system of claim 19, wherein the sensor comprises an optically sensitive detector.

25. The system of claim 24, wherein the optically sensitive detector comprises a photodiode sensitive to ultra-violet radiation.

26. The system of claim 19, wherein the sensor comprises a mounting device configured to mount the sensor to the electronic discharge device.

27. The system of claim 26, wherein the mounting device is configured to detachably mount the sensor to the electronic discharge device.

28. The system of claim 26, wherein the mounting device comprises a clip.

29. The system of claim 19, wherein the sensor is mounted on the electronic discharge device at a location that is spaced from a filament of the electronic discharge device to circumvent heat from the filament.

30. The system of claim 19, wherein the sensor is mounted on the electronic discharge device at a central location along a length of the electronic discharge device.

31. The system of claim 19, further comprising a shield mounted adjacent the sensor.

32. The system of claim 31, wherein the shield is formed of a material that is opaque to ultra-violet C (UVC) radiation.

33. The system of claim 31, wherein the shield is mounted between the sensor and an adjacent electronic discharge device.

34. The system of claim 33, wherein the shield is detachably mounted to the sensor.

35. A method of monitoring an operational status of an electronic discharge device in an air purification system comprising:
sensing radiation emitted from an electronic discharge device using an optically sensitive detector located within an purification system and in an optical path of the radiation emitted from the electronic discharge device;
generating an operational characteristic signal in response to the optical radiation sensed; and
determining an operational status of the electronic discharge device using the operational characteristic signal generated by the optically sensitive detector.

36. The method of claim 35, further comprising displaying an indication of the operational status of the electronic discharge device.

37. The method of claim 35, further comprising transmitting a status signal indicating the operational status of the electronic discharge device to a remote location.

38. The method of claim 35, further comprising receiving the status signal at the remote location.

39. A system for monitoring an operational status of an electronic discharge device in an air purification system comprising:
an optically sensitive detector located within an purification system and in an optical path of radiation emitted from an electronic discharge device, wherein the detector is configured to generate an operational characteristic signal based on a level of radiation detected;
a sensing circuit located proximate the air purification system and configured to receive input signals from the optically sensitive detector, determine an operational status of the electronic discharge device in response to the radiation sensed and transmit a status signal indicating the operational status of the electronic discharge device.

40. The system of claim 39, further comprising a monitoring unit configured to receive the status signal from the sensing circuit and display an indicator of the operational status of the electronic discharge device.

41. A method of retrofitting an air purification system for monitoring an operational status of an electronic discharge device in the air purification system comprising:
accessing an air purification system that comprises an electronic discharge device located within an air handling unit wherein the electronic discharge device is configured to expose air moving through the unit to radiation; and
installing within the purification system and in an optical path of the radiation emitted from the electronic discharge device an optically sensitive detector to detect radiation emitted from the electronic discharge device.
